(19) United States
(12) Patent Application Publication
(10) Pub. No.: US 2024/0232457 A1
(43) Pub. Date: Jul. 11, 2024

(54) TEST VALIDATION

(71) Applicant: GM Cruise Holdings LLC, San Francisco, CA (US)

(72) Inventors: Simon Murtha Smith, San Francisco, CA (US); Andrew Robinson, San Francisco, CA (US); Tobias Marc Rene Thiel, San Francisco, CA (US); Tatsuya Iwamoto, Foster City, CA (US)

(21) Appl. No.: 18/093,778

(22) Filed: Jan. 5, 2023

(51) Int. Cl. G06F 30/20; G06F 11/36

(52) U.S. Cl. CPC G06F 30/20; G06F 11/3664

(57) ABSTRACT

Aspects of the subject technology relate to systems, methods, and computer-readable media for validating a test associated with operation of an autonomous vehicle (AV). Road data generated in association with operation of an AV in a real-world environment is accessed. A simulation environment for running a software stack associated with controlling the AV is generated based on the road data. A portion of the software stack is modified and the modified software stack is run as part of a test using sensor data included as part of the road data. The test of the modified software stack is validated based on the running of the modified software stack in the simulation environment in relation to operation of the AV in the real-world environment.

### BACKGROUND

### 1. Technical Field

The present disclosure generally relates to validating an autonomous vehicle (AV) test and, more specifically, to validating a software stack test that is run in association with simulated operation of the AV.

### 2. Introduction

An AV is a motorized vehicle that can navigate without a human driver. An exemplary autonomous vehicle can include various sensors, such as a camera sensor, a light detection and ranging (LIDAR) sensor, and a radio detection and ranging (RADAR) sensor, amongst others. The sensors collect data and measurements that the autonomous vehicle can use for operations such as navigation. The sensors can provide the data and measurements to an internal computing system of the autonomous vehicle, which can use the data and measurements to control a mechanical system of the autonomous vehicle, such as a vehicle propulsion system, a braking system, or a steering system. Typically, the sensors are mounted at fixed locations on the autonomous vehicles.

### BRIEF DESCRIPTION OF THE DRAWINGS

The various advantages and features of the present technology will become apparent by reference to specific implementations illustrated in the appended drawings. A person of ordinary skill in the art will understand that these drawings only show some examples of the present technology and would not limit the scope of the present technology to these examples. Furthermore, the skilled artisan will appreciate the principles of the present technology as described and explained with additional specificity and detail through the use of the accompanying the drawings in which:

FIG. 1 illustrates an example system environment that can be used to facilitate AV dispatch and operations, according to some examples of the present disclosure;

FIG. 2 is a diagram illustrating an example simulation framework, according to some examples of the present disclosure;

FIG. 3 illustrates a flowchart for an example method of validating a test of an AV software stack that is run in a simulation environment, according to some examples of the present disclosure;

FIG. 4 illustrates a flowchart for an example method of implementing a modified software stack based on testing validation of the modified software stack, according to some examples of the present disclosure; and

FIG. 5 illustrates an example processor-based system with which some aspects of the subject technology can be implemented, according to some examples of the present disclosure.

### DETAILED DESCRIPTION

The detailed description set forth below is intended as a description of various configurations of the subject technology and is not intended to represent the only configurations in which the subject technology can be practiced. The appended drawings are incorporated herein and constitute a part of the detailed description. The detailed description includes specific details for the purpose of providing a more thorough understanding of the subject technology. However, it will be clear and apparent that the subject technology is not limited to the specific details set forth herein and may be practiced without these details. In some instances, structures and components are shown in block diagram form in order to avoid obscuring the concepts of the subject technology.

One aspect of the present technology is the gathering and use of data available from various sources to improve quality and experience. The present disclosure contemplates that in some instances, this gathered data may include personal information. The present disclosure contemplates that the entities involved with such personal information respect and value privacy policies and practices.

A software stack can be used to control an autonomous vehicle. In particular, a software stack can include various dependent processes that can be implemented to control an autonomous vehicle. In order to both develop the software stack and control an autonomous vehicle, a large amount of data is needed. Data for developing the software stack can be collected by the autonomous vehicle (AV) during operation. Specifically, the AV can record sensory information captured by sensors and outputs from various AV nodes during operation of the AV. Such data can be referred to as raw AV data or road data.

Gathered road data (i.e., data collected by sensors or other components of the AV as the AV traverses a physical road) can be used in various aspects of controlling operation of AVs. Specifically, road data can be used in generating a simulation environment. In turn, a software stack associated with controlling AVs can be tested in the simulation environment, e.g. using the road data as inputs. This is advantageous as modifications can be made to the software stack, e.g. different versions of the software stack can be created, and the modified software stack can be run in simulation without running in a real-world environment. As described here, in some cases simulations can be built based on actual operations of an AV in a real-world environment. However, when a software stack is modified and run in the simulation using real-world sensor data as input (e.g., road data), the simulated operations of the AV can deviate from the actual operations of the AV in the real-world environment. For example, an AV in the real world environment may turn right based on a first version of a software stack. However, upon simulated the same situation that was encountered in the real world and using a second version of the software stack, the simulated AV may deviate from the original action (e.g., turn left or go straight instead of turning right). In turn, this deviation can invalidate the test.

Tests can be invalidated by modifying the software stack and observing pose divergence between the simulation of the modified software stack and the real-world data that is used in generating the simulation. For example, a position of an AV can change during a simulated test relative to a real-world position of the AV that serves as the input for the simulation, thereby invalidating the test. Such pose divergence can ultimately be caused by differences in pose that are observed in a real-world environment and a simulated environment. Specifically, differences in AV pose in a perception software stack between a real-world environment and a simulated environment can ultimately lead to further divergence in pose and behaviors of the AV when subsequent software stacks, e.g. the control stack, are run. More specifically, differences in perception pose can have a cascading effect on pose variance as the software stacks are subsequently run after the perception stack. In turn, this can lead to greater pose divergence in such later run software stacks, thereby leading to test invalidation.

The disclosed technology addresses the problems associated with performing simulated tests of a modified software stack, by validating the tests of modified software stacks run in simulation through various techniques, such as path divergence, pose divergence, intent divergence, and output divergence of various systems that are run for the software stack. While the technology is described with respect to AV operation, the technology can be applied in an applicable operational environment where a software stack is run in a simulated environment created based on gathered real-world data.

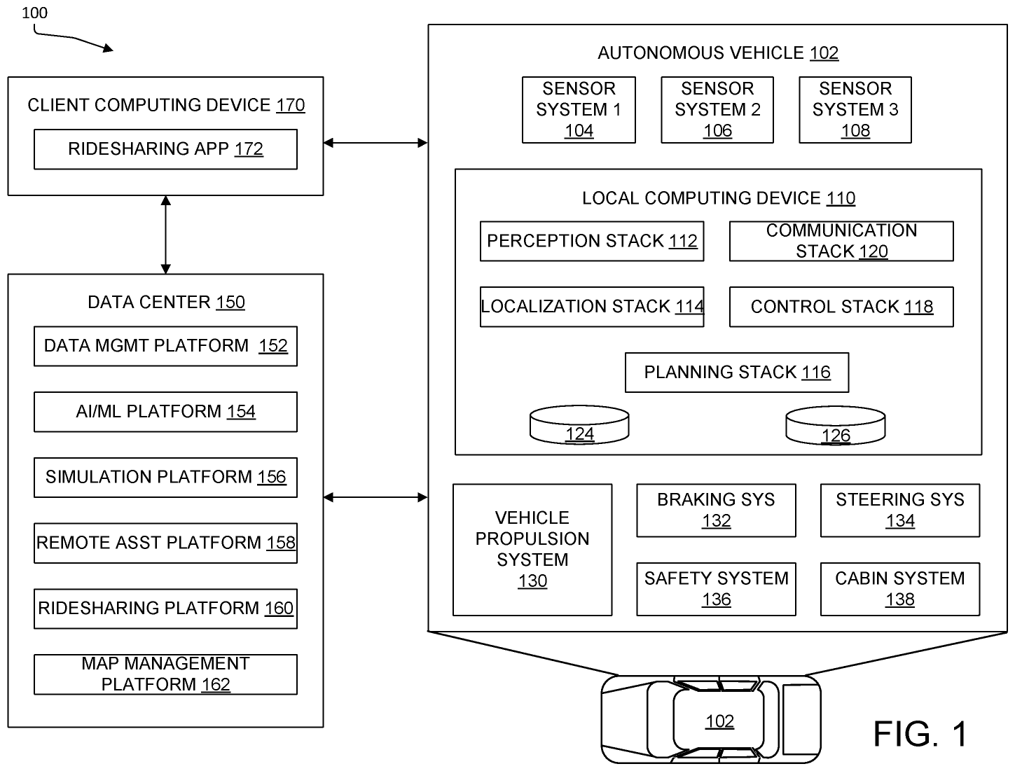

FIG. 1 illustrates an example of an AV management system 100. One of ordinary skill in the art will understand that, for the AV management system 100 and any system discussed in the present disclosure, there can be additional or fewer components in similar or alternative configurations. The illustrations and examples provided in the present disclosure are for conciseness and clarity. Other embodiments may include different numbers and/or types of elements, but one of ordinary skill the art will appreciate that such variations do not depart from the scope of the present disclosure.

In this example, the AV management system 100 includes an AV 102, a data center 150, and a client computing device 170. The AV 102, the data center 150, and the client computing device 170 can communicate with one another over one or more networks (not shown), such as a public network (e.g., the Internet, an Infrastructure as a Service (IaaS) network, a Platform as a Service (PaaS) network, a Software as a Service (SaaS) network, another Cloud Service Provider (CSP) network, etc.), a private network (e.g., a Local Area Network (LAN), a private cloud, a Virtual Private Network (VPN), etc.), and/or a hybrid network (e.g., a multi-cloud or hybrid cloud network, etc.).

AV 102 can navigate about roadways without a human driver based on sensor signals generated by multiple sensor systems 104, 106, and 108. The sensor systems 104-108 can include different types of sensors and can be arranged about the AV 102. For instance, the sensor systems 104-108 can comprise Inertial Measurement Units (IMUs), cameras (e.g., still image cameras, video cameras, etc.), light sensors (e.g., LIDAR systems, ambient light sensors, infrared sensors, etc.), RADAR systems, a Global Navigation Satellite System (GNSS) receiver, (e.g., Global Positioning System (GPS) receivers), audio sensors (e.g., microphones, Sound Navigation and Ranging (SONAR) systems, ultrasonic sensors, etc.), engine sensors, speedometers, tachometers, odometers, altimeters, tilt sensors, impact sensors, airbag sensors, seat occupancy sensors, open/closed door sensors, tire pressure sensors, rain sensors, and so forth. For example, the sensor system 104 can be a camera system, the sensor system 106 can be a LIDAR system, and the sensor system 108 can be a RADAR system. Other embodiments may include any other number and type of sensors.

AV 102 can also include several mechanical systems that can be used to maneuver or operate AV 102. For instance, the mechanical systems can include vehicle propulsion system 130, braking system 132, steering system 134, safety system 136, and cabin system 138, among other systems. Vehicle propulsion system 130 can include an electric motor, an internal combustion engine, or both. The braking system 132 can include an engine brake, a wheel braking system (e.g., a disc braking system that utilizes brake pads), hydraulics, actuators, and/or any other suitable componentry configured to assist in decelerating AV 102. The steering system 134 can include suitable componentry configured to control the direction of movement of the AV 102 during navigation. Safety system 136 can include lights and signal indicators, a parking brake, airbags, and so forth. The cabin system 138 can include cabin temperature control systems, in-cabin entertainment systems, and so forth. In some embodiments, the AV 102 may not include human driver actuators (e.g., steering wheel, handbrake, foot brake pedal, foot accelerator pedal, turn signal lever, window wipers, etc.) for controlling the AV 102. Instead, the cabin system 138 can include one or more client interfaces (e.g., Graphical User Interfaces (GUIs), Voice User Interfaces (VUIs), etc.) for controlling certain aspects of the mechanical systems 130-138.

AV 102 can additionally include a local computing device 110 that is in communication with the sensor systems 104-108, the mechanical systems 130-138, the data center 150, and the client computing device 170, among other systems. The local computing device 110 can include one or more processors and memory, including instructions that can be executed by the one or more processors. The instructions can make up one or more software stacks or components responsible for controlling the AV 102; communicating with the data center 150, the client computing device 170, and other systems; receiving inputs from riders, passengers, and other entities within the AV's environment; logging metrics collected by the sensor systems 104-108; and so forth. In this example, the local computing device 110 includes a perception stack 112, a mapping and localization stack 114, a planning stack 116, a control stack 118, a communications stack 120, an High Definition (HD) geospatial database 122, and an AV operational database 124, among other stacks and systems.

Perception stack 112 can enable the AV 102 to “see” (e.g., via cameras, LIDAR sensors, infrared sensors, etc.), “hear” (e.g., via microphones, ultrasonic sensors, RADAR, etc.), and “feel” (e.g., pressure sensors, force sensors, impact sensors, etc.) its environment using information from the sensor systems 104-108, the mapping and localization stack 114, the HD geospatial database 122, other components of the AV, and other data sources (e.g., the data center 150, the client computing device 170, third-party data sources, etc.). The perception stack 112 can detect and classify objects and determine their current and predicted locations, speeds, directions, and the like. In addition, the perception stack 112 can determine the free space around the AV 102 (e.g., to maintain a safe distance from other objects, change lanes, park the AV, etc.). The perception stack 112 can also identify environmental uncertainties, such as where to look for moving objects, flag areas that may be obscured or blocked from view, and so forth.

Mapping and localization stack 114 can determine the AV's position and orientation (pose) using different methods from multiple systems (e.g., GPS, IMUs, cameras, LIDAR, RADAR, ultrasonic sensors, the HD geospatial database 122, etc.). For example, in some embodiments, the AV 102 can compare sensor data captured in real-time by the sensor systems 104-108 to data in the HD geospatial database 122 to determine its precise (e.g., accurate to the order of a few centimeters or less) position and orientation. The AV 102 can focus its search based on sensor data from one or more first sensor systems (e.g., GPS) by matching sensor data from one or more second sensor systems (e.g., LIDAR). If the mapping and localization information from one system is unavailable, the AV 102 can use mapping and localization information from a redundant system and/or from remote data sources.

The planning stack 116 can determine how to maneuver or operate the AV 102 safely and efficiently in its environment. For example, the planning stack 116 can receive the location, speed, and direction of the AV 102, geospatial data, data regarding objects sharing the road with the AV 102 (e.g., pedestrians, bicycles, vehicles, ambulances, buses, cable cars, trains, traffic lights, lanes, road markings, etc.) or certain events occurring during a trip (e.g., an Emergency Vehicle (EMV) blaring a siren, intersections, occluded areas, street closures for construction or street repairs, Double-Parked Vehicles (DPVs), etc.), traffic rules and other safety standards or practices for the road, user input, and other relevant data for directing the AV 102 from one point to another. The planning stack 116 can determine multiple sets of one or more mechanical operations that the AV 102 can perform (e.g., go straight at a specified speed or rate of acceleration, including maintaining the same speed or decelerating; turn on the left blinker, decelerate if the AV is above a threshold range for turning, and turn left; turn on the right blinker, accelerate if the AV is stopped or below the threshold range for turning, and turn right; decelerate until completely stopped and reverse; etc.), and select the best one to meet changing road conditions and events. If something unexpected happens, the planning stack 116 can select from multiple backup plans to carry out. For example, while preparing to change lanes to turn right at an intersection, another vehicle may aggressively cut into the destination lane, making the lane change unsafe. The planning stack 116 could have already determined an alternative plan for such an event, and upon its occurrence, help to direct the AV 102 to go around the block instead of blocking a current lane while waiting for an opening to change lanes.

The control stack 118 can manage the operation of the vehicle propulsion system 130, the braking system 132, the steering system 134, the safety system 136, and the cabin system 138. The control stack 118 can receive sensor signals from the sensor systems 104-108 as well as communicate with other stacks or components of the local computing device 110 or a remote system (e.g., the data center 150) to effectuate operation of the AV 102. For example, the control stack 118 can implement the final path or actions from the multiple paths or actions provided by the planning stack 116. This can involve turning the routes and decisions from the planning stack 116 into commands for the actuators that control the AV's steering, throttle, brake, and drive unit.

The communication stack 120 can transmit and receive signals between the various stacks and other components of the AV 102 and between the AV 102, the data center 150, the client computing device 170, and other remote systems. The communication stack 120 can enable the local computing device 110 to exchange information remotely over a network, such as through an antenna array or interface that can provide a metropolitan WIFI® network connection, a mobile or cellular network connection (e.g., Third Generation (3G), Fourth Generation (4G), Long-Term Evolution (LTE), 5th Generation (5G), etc.), and/or other wireless network connection (e.g., License Assisted Access (LAA), Citizens Broadband Radio Service (CBRS), MULTEFIRE, etc.). The communication stack 120 can also facilitate local exchange of information, such as through a wired connection (e.g., a user's mobile computing device docked in an in-car docking station or connected via Universal Serial Bus (USB), etc.) or a local wireless connection (e.g., Wireless Local Area Network (WLAN), Bluetooth®, infrared, etc.).

The HD geospatial database 122 can store HD maps and related data of the streets upon which the AV 102 travels. In some embodiments, the HD maps and related data can comprise multiple layers, such as an areas layer, a lanes and boundaries layer, an intersections layer, a traffic controls layer, and so forth. The areas layer can include geospatial information indicating geographic areas that are drivable (e.g., roads, parking areas, shoulders, etc.) or not drivable (e.g., medians, sidewalks, buildings, etc.), drivable areas that constitute links or connections (e.g., drivable areas that form the same road) versus intersections (e.g., drivable areas where two or more roads intersect), and so on. The lanes and boundaries layer can include geospatial information of road lanes (e.g., lane or road centerline, lane boundaries, type of lane boundaries, etc.) and related attributes (e.g., direction of travel, speed limit, lane type, etc.). The lanes and boundaries layer can also include 3D attributes related to lanes (e.g., slope, elevation, curvature, etc.). The intersections layer can include geospatial information of intersections (e.g., crosswalks, stop lines, turning lane centerlines, and/or boundaries, etc.) and related attributes (e.g., permissive, protected/permissive, or protected only left turn lanes; permissive, protected/permissive, or protected only U-turn lanes; permissive or protected only right turn lanes; etc.). The traffic controls layer can include geospatial information of traffic signal lights, traffic signs, and other road objects and related attributes.

The AV operational database 124 can store raw AV data generated by the sensor systems 104-108 and other components of the AV 102 and/or data received by the AV 102 from remote systems (e.g., the data center 150, the client computing device 170, etc.). In some embodiments, the raw AV data can include HD LIDAR point cloud data, image or video data, RADAR data, GPS data, and other sensor data that the data center 150 can use for creating or updating AV geospatial data.

The data center 150 can be a private cloud (e.g., an enterprise network, a co-location provider network, etc.), a public cloud (e.g., an Infrastructure as a Service (IaaS) network, a Platform as a Service (PaaS) network, a Software as a Service (SaaS) network, or other Cloud Service Provider (CSP) network), a hybrid cloud, a multi-cloud, and so forth. The data center 150 can include one or more computing devices remote to the local computing device 110 for managing a fleet of AVs and AV-related services. For example, in addition to managing the AV 102, the data center 150 may also support a ridesharing service, a delivery service, a remote/roadside assistance service, street services (e.g., street mapping, street patrol, street cleaning, street metering, parking reservation, etc.), and the like.

The data center 150 can send and receive various signals to and from the AV 102 and the client computing device 170. These signals can include sensor data captured by the sensor systems 104-108, roadside assistance requests, software updates, ridesharing pick-up and drop-off instructions, and so forth. In this example, the data center 150 includes one or more of a data management platform 152, an Artificial Intelligence/Machine Learning (AI/ML) platform 154, a simulation platform 156, a remote assistance platform 158, a ridesharing platform 160, and a map management platform 162, among other systems.

Data management platform 152 can be a “big data” system capable of receiving and transmitting data at high speeds (e.g., near real-time or real-time), processing a large variety of data, and storing large volumes of data (e.g., terabytes, petabytes, or more of data). The varieties of data can include data having different structures (e.g., structured, semi-structured, unstructured, etc.), data of different types (e.g., sensor data, mechanical system data, ridesharing service data, map data, audio data, video data, etc.), data associated with different types of data stores (e.g., relational databases, key-value stores, document databases, graph databases, column-family databases, data analytic stores, search engine databases, time series databases, object stores, file systems, etc.), data originating from different sources (e.g., AVs, enterprise systems, social networks, etc.), data having different rates of change (e.g., batch, streaming, etc.), or data having other heterogeneous characteristics. The various platforms and systems of the data center 150 can access data stored by the data management platform 152 to provide their respective services.

The AI/ML platform 154 can provide the infrastructure for training and evaluating machine learning algorithms for operating the AV 102, the simulation platform 156, the remote assistance platform 158, the ridesharing platform 160, the map management platform 162, and other platforms and systems. Using the AI/ML platform 154, data scientists can prepare data sets from the data management platform 152; select, design, and train machine learning models; evaluate, refine, and deploy the models; maintain, monitor, and retrain the models; and so on.

The simulation platform 156 can enable testing and validation of the algorithms, machine learning models, neural networks, and other development efforts for the AV 102, the remote assistance platform 158, the ridesharing platform 160, the map management platform 162, and other platforms and systems. The simulation platform 156 can replicate a variety of driving environments and/or reproduce real-world scenarios from data captured by the AV 102 and from third party sources, including rendering geospatial information and road infrastructure (e.g., streets, lanes, crosswalks, traffic lights, stop signs, etc.) obtained from the map management platform 162; modeling the behavior of other vehicles, bicycles, pedestrians, and other dynamic elements; simulating inclement weather conditions, different traffic scenarios; and so on.

The remote assistance platform 158 can generate and transmit instructions regarding the operation of the AV 102. For example, in response to an output of the AI/ML platform 154 or other system of the data center 150, the remote assistance platform 158 can prepare instructions for one or more stacks or other components of the AV 102.

The ridesharing platform 160 can interact with a customer of a ridesharing service via a ridesharing application 172 executing on the client computing device 170. The client computing device 170 can be any type of computing system, including a server, desktop computer, laptop, tablet, smartphone, smart wearable device (e.g., smart watch; smart eyeglasses or other Head-Mounted Display (HMD); smart ear pods or other smart in-ear, on-ear, or over-ear device; etc.), gaming system, or other general purpose computing device for accessing the ridesharing application 172. The client computing device 170 can be a customer's mobile computing device or a computing device integrated with the AV 102 (e.g., the local computing device 110). The ridesharing platform 160 can receive requests to be picked up or dropped off from the ridesharing application 172 and dispatch the AV 102 for the trip.

Map management platform 162 can provide a set of tools for the manipulation and management of geographic and spatial (geospatial) and related attribute data. The data management platform 152 can receive LIDAR point cloud data, image data (e.g., still image, video, etc.), RADAR data, GPS data, and other sensor data (e.g., raw data) from one or more AVs 102, Unmanned Aerial Vehicles (UAVs), satellites, third-party mapping services, and other sources of geospatially referenced data. The raw data can be processed, and map management platform 162 can render base representations (e.g., tiles (2D), bounding volumes (3D), etc.) of the AV geospatial data to enable users to view, query, label, edit, and otherwise interact with the data. Map management platform 162 can manage workflows and tasks for operating on the AV geospatial data. Map management platform 162 can control access to the AV geospatial data, including granting or limiting access to the AV geospatial data based on user-based, role-based, group-based, task-based, and other attribute-based access control mechanisms. Map management platform 162 can provide version control for the AV geospatial data, such as to track specific changes that (human or machine) map editors have made to the data and to revert changes when necessary. Map management platform 162 can administer release management of the AV geospatial data, including distributing suitable iterations of the data to different users, computing devices, AVs, and other consumers of HD maps. Map management platform 162 can provide analytics regarding the AV geospatial data and related data, such as to generate insights relating to the throughput and quality of mapping tasks.

In some embodiments, the map viewing services of map management platform 162 can be modularized and deployed as part of one or more of the platforms and systems of the data center 150. For example, the AI/ML platform 154 may incorporate the map viewing services for visualizing the effectiveness of various object detection or object classification models, the simulation platform 156 may incorporate the map viewing services for recreating and visualizing certain driving scenarios, the remote assistance platform 158 may incorporate the map viewing services for replaying traffic incidents to facilitate and coordinate aid, the ridesharing platform 160 may incorporate the map viewing services into the client application 172 to enable passengers to view the AV 102 in transit en route to a pick-up or drop-off location, and so on.

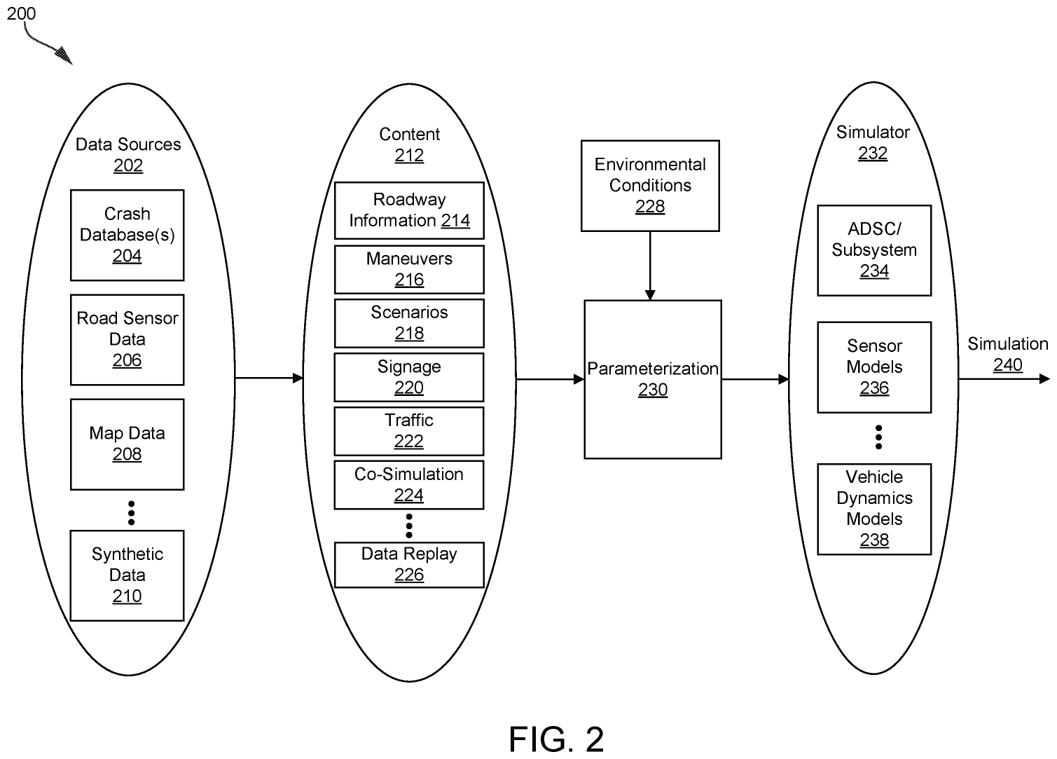

FIG. 2 is a diagram illustrating an example simulation framework 200, according to some examples of the present disclosure. The example simulation framework 200 can include data sources 202, content 212, environmental conditions 228, parameterization 230, and a simulator 232. The components in the example simulation framework 200 are merely illustrative examples provided for explanation purposes. In other examples, the simulation framework 200 can include other components that are not shown in FIG. 2 and/or more or less components than shown in FIG. 2.

The data sources 202 can be used to create a simulation. The data sources 202 can include, for example and without limitation, one or more crash databases 204, road sensor data 206, map data 208, and/or synthetic data 210. In other examples, the data sources 202 can include more or less sources than shown in FIG. 2 and/or one or more data sources that are not shown in FIG. 2.

The crash databases 204 can include crash data (e.g., data describing crashes and/or associated details) generated by vehicles involved in crashes. The road sensor data 206 can include data collected by one or more sensors (e.g., one or more camera sensors, LIDAR sensors, RADAR sensors, SONAR sensors, IMU sensors, GPS/GNSS receivers, and/or any other sensors) of one or more vehicles while the one or more vehicles drive/navigate one or more real-world environments. The map data 208 can include one or more maps (and, in some cases, associated data) such as, for example and without limitation, one or more high-definition (HD) maps, sensor maps, scene maps, and/or any other maps. In some examples, the one or more HD maps can include roadway information such as, for example, lane widths, location of road signs and traffic lights, directions of travel for each lane, road junction information, speed limit information, etc.

The synthetic data 210 can include virtual assets, objects, and/or elements created for a simulated scene, a virtual scene and/or virtual scene elements, and/or any other synthetic data elements. For example, in some cases, the synthetic data 210 can include one or more virtual vehicles, virtual pedestrians, virtual roads, virtual objects, virtual environments/scenes, virtual signs, virtual backgrounds, virtual buildings, virtual trees, virtual motorcycles/bicycles, virtual obstacles, virtual environmental elements (e.g., weather, lightening, shadows, etc.), virtual surfaces, etc.

In some examples, data from some or all of the data sources 202 can be used to create the content 212. The content 212 can include static content and/or dynamic content. For example, the content 212 can include roadway information 214, maneuvers 216, scenarios 218, signage 220, traffic 222, co-simulation 224, and/or data replay 226. The roadway information 214 can include, for example, lane information (e.g., number of lanes, lane widths, directions of travel for each lane, etc.), the location and information of road signs and/or traffic lights, road junction information, speed limit information, road attributes (e.g., surfaces, angles of inclination, curvatures, obstacles, etc.), road topologies, and/or other roadway information. The maneuvers 216 can include any AV maneuvers, and the scenarios 218 can include specific AV behaviors in certain AV scenes/environments. The signage 220 can include signs such as, for example, traffic lights, road signs, billboards, displayed messages on the road, etc. The traffic 222 can include any traffic information such as, for example, traffic density, traffic fluctuations, traffic patterns, traffic activity, delays, positions of traffic, velocities, volumes of vehicles in traffic, geometries or footprints of vehicles, pedestrians, spaces (occupied and/or unoccupied), etc.

The co-simulation 224 can include a distributed modeling and simulation of different AV subsystems that form the larger AV system. In some cases, the co-simulation 224 can include information for connecting separate simulations together with interactive communications. In some cases, the co-simulation 224 can allow for modeling to be done at a subsystem level while providing interfaces to connect the subsystems to the rest of the system (e.g., the autonomous driving system computer). Moreover, the data replay 226 can include replay content produced from real-world sensor data (e.g., road sensor data 206).

The environmental conditions 228 can include any information about environmental conditions 228. For example, the environmental conditions 228 can include atmospheric conditions, road/terrain conditions (e.g., surface slope or gradient, surface geometry, surface coefficient of friction, road obstacles, etc.), illumination, weather, road and/or scene conditions resulting from one or more environmental conditions, etc.

The content 212 and the environmental conditions 228 can be used to create the parameterization 230. The parameterization 230 can include parameter ranges, parameterized scenarios, probability density functions of one or more parameters, sampled parameter values, parameter spaces to be tested, evaluation windows for evaluating a behavior of an AV in a simulation, scene parameters, content parameters, environmental parameters, etc. The parameterization 230 can be used by a simulator 232 to generate a simulation 240.

The simulator 232 can include a software engine(s), algorithm(s), neural network model(s), and/or software component(s) used to generate simulations, such as simulation 240. In some examples, the simulator 232 can include autonomous driving system computers/subsystem models 234, sensor models 236, and a vehicle dynamics model 238. The autonomous driving system computers/subsystem models 234 can include models, descriptors, and/or interfaces for the autonomous driving system computer and/or autonomous driving system computer subsystems such as, for example, a perception stack (e.g., perception stack 112), a localization stack (e.g., localization stack 114), a prediction stack (e.g., prediction stack 116), a planning stack (e.g., planning stack 118), a communications stack (e.g., communications stack 120), a control stack (e.g., control stack 122), a sensor system(s), and/or any other subsystems.

The sensor models 236 can include mathematical representations of hardware sensors and an operation (e.g., sensor data processing) of one or more sensors (e.g., a LIDAR, a RADAR, a SONAR, a camera sensor, an IMU, and/or any other sensor). The vehicle dynamics model 238 can model vehicle behaviors/operations, vehicle attributes, vehicle trajectories, vehicle positions, etc.

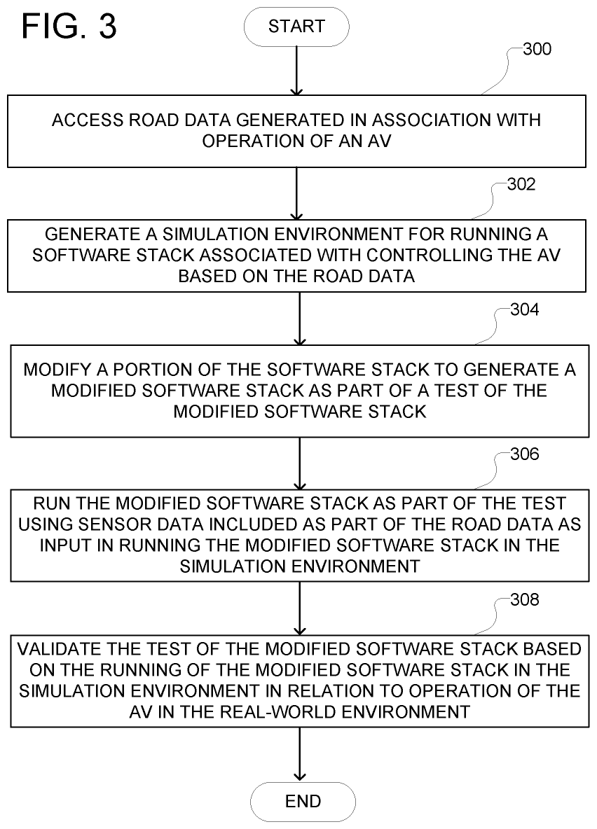

The disclosure now continues with a discussion of validating simulation tests. Specifically, FIG. 3 illustrates a flowchart for an example method of validating a test of an AV software stack that is run in a simulation environment. The method shown in FIG. 3 is provided by way of example, as there are a variety of ways to carry out the method. Additionally, while the example method is illustrated with a particular order of operations, those of ordinary skill in the art will appreciate that FIG. 3 and the modules shown therein can be executed in any order and can include fewer or more modules than illustrated. Each module shown in FIG. 3 represents one or more operations, processes, methods or routines in the method.

At operation 300, road data associated with operation of an AV in a real-world environment is accessed. Road data can include applicable data that is gathered by an AV as the AV operates in a real-world environment. Specifically, road data can include sensor data that is gathered by sensors as the AV performs various maneuvers in a real-world environment. For example, road data can include data captured by a LIDAR sensor that is indicative of agents surrounding an AV in an environment.

Road data can also include data that is generated in running a software stack associated with operation of an AV. Specifically, road data can include data that is generated by running all or a portion of the software stacks shown in FIG. 1. For example, road data can include an output of running a prediction stack. In turn, the output of the prediction stack can include an indication of agents in an environment. Further, road data can be indicative of positions and trajectories of agents in an environment. Specifically, the output of the prediction stack can include trajectories of agents in the environment as the agents move, e.g. relative to an AV. For example, road data can include a trajectory of a car driving next to an AV in a real-world environment.

At operation 302, a simulation environment for running a software stack associated with controlling the AV is generated. Reference to a software stack, as used herein, can correspond to a specific version of a software stack that is a logical configuration of a set of high level components or pieces. In turn, changes to a software stack can represent different versions of the same software stack. The simulation environment can be implemented through applicable techniques, such as the techniques described with respect to the simulation framework 200. Specifically, the simulation environment can be generated based on the road data that is accessed at operation 300. More specifically, sensor data that is gathered by the AV as part of the road data during operation of the AV in the real-world environment can serve as input for parameterization in generating the simulation environment.

A simulation environment, as used herein, can include an environment in which a software stack can be run as part of a simulation or otherwise test of the software stack. Specifically, the simulation environment can include a recreation of a real-world environment in which the AV is operated to gather the road data. For example, the simulation environment can include a recreation of agents that are in the real-world environment in which the AV operates to gather the road data.

At operation 304, a portion of the software stack is modified to generate a modified software stack. Specifically, a portion of the software stack can be modified as part of a test of a modified stack that can be run in the simulation environment. In modifying a software stack, processes can be removed from the software stack, processes can be added to the software stack, and/or processes can be modified within the software stack. For example, the planning system can be changed to increase following distances of the AV with respect to other vehicles. In another example, functions for estimating other vehicle's velocities can be changed.

In modifying a portion of the software stack, a specific, or otherwise selected, portion of the software stack can be modified. Specifically, one or more of a perception process, a prediction process, a planning process, a communication process, and a control process of a software stack of the AV can be modified to create the modified software stack. The selected portion of the software stack can be modified in order to test changes to the software stack. For example, a new version of a control process in the software stack can be released. As follows, the software stack can be modified to include the new version of the control process and subsequently tested as part of testing the new version of the control process.

At operation 306, the modified software stack is run as part of the test. Specifically, the modified software stack is run in the simulation environment using sensor input data that is included as part of the road data. More specifically, the sensor input data can be input into the modified software stack, and the modified software stack can be run in the simulation environment based on the sensor input data. Sensor input data includes applicable data gathered by the sensors of the AV during operation of the AV in the real-world environment. Specifically, sensor input data can include detected sensor data of agents in the real-world environment in relation to the AV. For example, sensor input data can include LIDAR data of a car in front of the AV.

The modified software stack can be run while keeping a simulated pose of the perception software stack unchanged. Specifically, the simulated pose of the AV by the perception portion of the software stack can be kept consistent with a real-world pose of the AV, e.g. represented by the real-world data. More specifically, the perception portion of the software stack, while in simulation, can parse sensor data from a source that is representative of a reference pose of the AV in the real-world environment instead of the simulated environment. The pose of the perception stack can be kept consistent with the real-world environment while the pose of other applicable portions of the software stack can be allowed to diverge with respect to the real-world environment. Specifically, the simulated pose of the planning stack and the control stack can diverge with respect to the pose of the AV in the planning stack and the control stack in the real-world environment.

At operation 308, the test of the modified software stack is validated based on the running of the modified software stack in the simulation environment. Specifically, the test of the modified software stack is validated based on running of the modified software stack in relation to operation of the AV in the real-world environment. Test validation, as used herein, can include verifying that the test of the modified software stack can be relied on as an accurate simulation of the modified software stack with the fixed sensor data serving as input to the test. Conversely, test validation can also include verifying that the test of the modified software stack cannot be relied on as an accurate simulation of the modified software stack, or otherwise invalidated, with the fixed sensor data serving as input to the test.

The test of the modified software stack can be validated based on a position of the AV in the test in relation to a position of the AV in the real-world environment. Specifically, the test of the modified software stack can be validated based on a difference between a position of the AV in the test and a position of the AV in the real-world environment, e.g. in relation to a threshold. For example, if a position of the AV in the test is greater than a certain amount from a position of the AV in the real-world environment, then the test can be declared as invalid. Positions in the test and the real-world environment can temporally correspond to each other. For example, at a specific time in the real-world environment, the AV can be stopped at a stop sign. As follows, the position of the AV during the test at the specific time, e.g. in relation to the stop sign, can be used in determining whether the test is valid.

Further, the test of the modified software stack can be validated based on an orientation of the AV in the test in relation to an orientation of the AV in the real-world environment. Specifically, the test of the modified software can be validated based on a difference between an orientation of the AV in the test and an orientation of the AV in the real-world environment, e.g. in relation to a threshold. For example, if an orientation of the AV in the test is different from an orientation of the AV in the real-world environment by a threshold amount, then the test can be declared as invalid. Orientations in the test and the real-world environment can temporally correspond to each other. For example, at a specific time in the real-world environment, the AV can be turned 90° with respect to another car. As follows, the orientation of the AV during the test at the specific time, e.g. in relation to the car, can be used to determine whether the test is valid.

In validating the test of the modified software stack based on either or both a position and an orientation, e.g. a pose, of the AV in the test in relation to a position and orientation of the AV in the real-world environment, the test can be validated based on the pose at a portion of the software stack. Specifically, a pose of the AV in executing a control portion of the software stack in the real-world environment can be compared to a pose of the AV in executing a control portion of the modified software stack in the test environment. As follows, the test of the modified software stack can be invalidated based on the divergence between the pose in executing the control portion of the software stack in the real-world environment and the pose in executing the control portion of the modified software stack in the real-world environment.

The test of the modified software stack can be validated based on paths of the AV in both the simulated environment and the real-world environment. Specifically, the test of the modified software stack can be validated based on a comparison between a simulated path of the AV in the simulated environment and an actual path traversed by the AV in the real-world environment. More specifically, the test can be validated based on a quantification of an amount of divergence, e.g. in relation to a threshold, between a simulated path of the AV and an actual path traversed by the AV. For example, an AV can move along a trajectory that follows a car in front of the AV in the real-world environment. Further in the example, the AV in the simulated environment can also move along the same trajectory that follows the car. As a result, the test can be validated based on the lack of divergence between the real-world and simulated paths of the AV. In another example, an AV can move within 4 meters of a car in front of the AV in the real-world environment. However, in the simulated environment, the AV can move within two meters of the car in front of the AV. As follows, the test can be invalidated based on this divergence between the real-world and simulated paths of the AV.

Additionally, the test of the modified software stack can be validated based on an intent of the test of the modified software stack in simulation. Specifically, the test of the modified software stack can also be validated based on a real-world intent of the AV in operation of the AV in the real-world and a simulated intent of the AV in the test of the modified software stack. An intent of the AV in operation in either the real-world or the simulation environment includes an applicable desired maneuver to be performed by the AV. For example, an intent of the AV in operation can include that the car intended to turn right. Such intents can be reflected through control instructions that are created in running the software stack, e.g. through to the control processes. For example, an intent of the AV can be reflected in the control commands of brake checking in controlling the operation of the AV through the software stack.

In validating the test based on a real-world intent and a simulated intent of the AV, the test can be invalidated based on a comparison between the real-world intent and the simulated intent. Specifically, differences between the real-world intent and the simulated intent can be identified. As follows, the test can be invalidated based on the differences between intents, e.g. based on a quantification of the intents or another applicable metric. For example, a real-world intent of an AV can indicate that the AV will assert before another agent in a scene. Further in the example, the simulated intent for a test can include that the AV will not assert before the other agent in the scene. As a result, the test can be invalidated based on the existence of different intents. In another example, if the AV turned right in a real-world environment during a specific scenario but turned left in a simulated test when confronted with the same scenario or a similar scenario in the simulated environment, then the test can be declared invalid.

Further, the test of the modified software stack can be validated based on perception outputs of the corresponding stacks run in the real-world environment and the simulation environment. Specifically, a perception output of the operation of the AV in the real-world environment can be compared to a perception output of a test of the operation of the AV in the simulated environment. As follows, the test can be validated based on the differences between the outputs in the real-world environment and the simulated environment. For example, a blind spot can exist in the real-world environment, as indicated by perception data of the real-world environment. Further in the example, the region where the blind spot is located in the simulated environment can be visible in a test performed in the simulated environment. As a result, the test can be invalidated based on this discrepancy in visibility of a blind spot. In another example, a ray can be traced back to a point in the real-world environment. However, the ray in the simulated environment can not be traced back to the same point as it was in the real-world environment. As a result, the test can be invalidated based on this discrepancy in ray tracing.

The test of the modified software stack can be validated based on keeping a pose in running a perception portion of the modified software stack during simulation consistent with a pose in running a perception portion of the software stack in the real-world environment. Specifically, one or a combination of path divergence, pose divergence, intent divergence, and output divergence of various systems that are run for the software stack can be used in validating the test while the pose of the perception portion of the software stack is kept consistent between the test environment and the real-world environment. For example, a pose of the AV in running a perception portion of the modified software stack in a simulated test can be kept consistent with a pose of the AV in running the perception portion of the software stack in the real-world environment. As follows, the ultimate path of the AV in the real-world environment can be compared to the path of the AV in the simulated test while the pose in the perception portion of the stacks is kept consistent between the simulated environment and real-world environment. Then, the divergence between the path of the AV in the real-world environment can be compared to the path of the AV in the simulated test to determine whether the simulated test is invalid. For example, if the car turned right in its path under a certain scenario in the real-world environment and turned left in its path in under the same scenario in the simulated environment, then the test can be declared invalid.

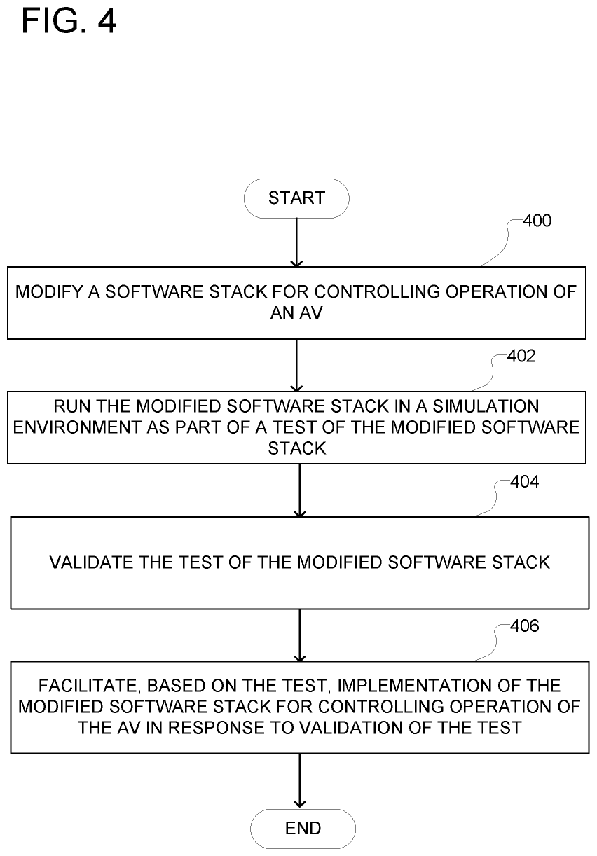

The disclosure now continues with a discussion of implementing modified software stacks that have had validated testing in simulation. Specifically, FIG. 4 illustrates a flowchart for an example method of implementing a modified software stack based on testing validation of the modified software stack. The method shown in FIG. 4 is provided by way of example, as there are a variety of ways to carry out the method. Additionally, while the example method is illustrated with a particular order of operations, those of ordinary skill in the art will appreciate that FIG. 3 and the modules shown therein can be executed in any order and can include fewer or more modules than illustrated. Each module shown in FIG. 4 represents one or more operations, processes, methods or routines in the method.

At operation 400, a software stack for controlling operation of an AV is modified. The software stack can be modified as part of a new version of the software stack. Further, the software stack can be modified as part of routine testing of the software stack.

At operation 402, the modified stack is run in a simulation environment as part of a test of the modified software stack. Specifically, a simulation environment can be generated based on gathered road data according to the techniques described herein. As follows, the gathered road data can be used to run the modified software stack in the simulation environment.

At operation 404, the test of the modified software stack is validated. The test of the modified software stack can be validated according to the techniques described herein.

Specifically, the test of the modified software stack can be verified as valid or invalid according to the techniques described herein.

At operation 406, implementation of the modified software stack is facilitated for controlling operation of the AV in response to validation of the test. Specifically, if the test is determined to be valid, then next steps for ultimately implementing the software stack in controlling the AV can be facilitated.

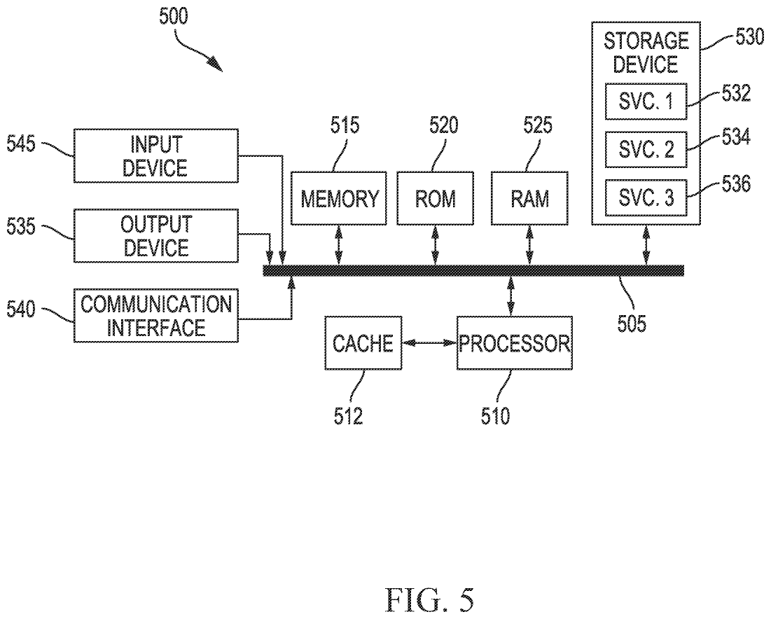

FIG. 5 illustrates an example processor-based system with which some aspects of the subject technology can be implemented. For example, processor-based system 500 can be any computing device making up, or any component thereof in which the components of the system are in communication with each other using connection 505. Connection 505 can be a physical connection via a bus, or a direct connection into processor 510, such as in a chipset architecture. Connection 505 can also be a virtual connection, networked connection, or logical connection.

In some embodiments, computing system 500 is a distributed system in which the functions described in this disclosure can be distributed within a datacenter, multiple data centers, a peer network, etc. In some embodiments, one or more of the described system components represents many such components each performing some or all of the function for which the component is described. In some embodiments, the components can be physical or virtual devices.

Example system 500 includes at least one processing unit (Central Processing Unit (CPU) or processor) 510 and connection 505 that couples various system components including system memory 515, such as Read-Only Memory (ROM) 520 and Random-Access Memory (RAM) 525 to processor 510. Computing system 500 can include a cache of high-speed memory 512 connected directly with, in close proximity to, or integrated as part of processor 510.

Processor 510 can include any general-purpose processor and a hardware service or software service, such as services 532, 534, and 536 stored in storage device 530, configured to control processor 510 as well as a special-purpose processor where software instructions are incorporated into the actual processor design. Processor 510 may essentially be a completely self-contained computing system, containing multiple cores or processors, a bus, memory controller, cache, etc. A multi-core processor may be symmetric or asymmetric.

To enable user interaction, computing system 500 includes an input device 545, which can represent any number of input mechanisms, such as a microphone for speech, a touch-sensitive screen for gesture or graphical input, keyboard, mouse, motion input, speech, etc. Computing system 500 can also include output device 535, which can be one or more of a number of output mechanisms known to those of skill in the art. In some instances, multimodal systems can enable a user to provide multiple types of input/output to communicate with computing system 500. Computing system 500 can include communications interface 540, which can generally govern and manage the user input and system output. The communication interface may perform or facilitate receipt and/or transmission wired or wireless communications via wired and/or wireless transceivers, including those making use of an audio jack/plug, a microphone jack/plug, a Universal Serial Bus (USB) port/plug, an Apple® Lightning® port/plug, an Ethernet port/plug, a fiber optic port/plug, a proprietary wired port/plug, a BLUETOOTH® wireless signal transfer, a BLUETOOTH® low energy (BLE) wireless signal transfer, an IBEACON® wireless signal transfer, a Radio-Frequency Identification (RFID) wireless signal transfer, Near-Field Communications (NFC) wireless signal transfer, Dedicated Short Range Communication (DSRC) wireless signal transfer, 802.11 Wi-Fi® wireless signal transfer, Wireless Local Area Network (WLAN) signal transfer, Visible Light Communication (VLC) signal transfer, Worldwide Interoperability for Microwave Access (WiMAX), Infrared (IR) communication wireless signal transfer, Public Switched Telephone Network (PSTN) signal transfer, Integrated Services Digital Network (ISDN) signal transfer, 3G/4G/5G/LTE cellular data network wireless signal transfer, ad-hoc network signal transfer, radio wave signal transfer, microwave signal transfer, infrared signal transfer, visible light signal transfer signal transfer, ultraviolet light signal transfer, wireless signal transfer along the electromagnetic spectrum, or some combination thereof.

Communication interface 540 may also include one or more Global Navigation Satellite System (GNSS) receivers or transceivers that are used to determine a location of the computing system 500 based on receipt of one or more signals from one or more satellites associated with one or more GNSS systems. GNSS systems include, but are not limited to, the US-based Global Positioning System (GPS), the Russia-based Global Navigation Satellite System (GLONASS), the China-based BeiDou Navigation Satellite System (BDS), and the Europe-based Galileo GNSS. There is no restriction on operating on any particular hardware arrangement, and therefore the basic features here may easily be substituted for improved hardware or firmware arrangements as they are developed.

Storage device 530 can be a non-volatile and/or non-transitory and/or computer-readable memory device and can be a hard disk or other types of computer readable media which can store data that are accessible by a computer, such as magnetic cassettes, flash memory cards, solid state memory devices, digital versatile disks, cartridges, a floppy disk, a flexible disk, a hard disk, magnetic tape, a magnetic strip/stripe, any other magnetic storage medium, flash memory, memristor memory, any other solid-state memory, a Compact Disc (CD) Read Only Memory (CD-ROM) optical disc, a rewritable CD optical disc, a Digital Video Disk (DVD) optical disc, a Blu-ray Disc (BD) optical disc, a holographic optical disk, another optical medium, a Secure Digital (SD) card, a micro SD (microSD) card, a Memory Stick® card, a smartcard chip, a EMV chip, a Subscriber Identity Module (SIM) card, a mini/micro/nano/pico SIM card, another Integrated Circuit (IC) chip/card, Random-Access Memory (RAM), Atatic RAM (SRAM), Dynamic RAM (DRAM), Read-Only Memory (ROM), Programmable ROM (PROM), Erasable PROM (EPROM), Electrically Erasable PROM (EEPROM), flash EPROM (FLASHEPROM), cache memory (L1/L2/L3/L4/L5/L #), Resistive RAM (RRAM/ReRAM), Phase Change Memory (PCM), Spin Transfer Torque RAM (STT-RAM), another memory chip or cartridge, and/or a combination thereof.

Storage device 530 can include software services, servers, services, etc., that when the code that defines such software is executed by the processor 510, it causes the system 500 to perform a function. In some embodiments, a hardware service that performs a particular function can include the software component stored in a computer-readable medium in connection with the necessary hardware components, such as processor 510, connection 505, output device 535, etc., to carry out the function.

Embodiments within the scope of the present disclosure may also include tangible and/or non-transitory computer-readable storage media or devices for carrying or having computer-executable instructions or data structures stored thereon. Such tangible computer-readable storage devices can be any available device that can be accessed by a general purpose or special purpose computer, including the functional design of any special purpose processor as described above. By way of example, and not limitation, such tangible computer-readable devices can include RAM, ROM, EEPROM, CD-ROM or other optical disk storage, magnetic disk storage or other magnetic storage devices, or any other device which can be used to carry or store desired program code in the form of computer-executable instructions, data structures, or processor chip design. When information or instructions are provided via a network or another communications connection (either hardwired, wireless, or combination thereof) to a computer, the computer properly views the connection as a computer-readable medium. Thus, any such connection is properly termed a computer-readable medium. Combinations of the above should also be included within the scope of the computer-readable storage devices.

Computer-executable instructions include, for example, instructions and data which cause a general-purpose computer, special purpose computer, or special purpose processing device to perform a certain function or group of functions. Computer-executable instructions also include program modules that are executed by computers in stand-alone or network environments. Generally, program modules include routines, programs, components, data structures, objects, and the functions inherent in the design of special-purpose processors, etc. that perform tasks or implement abstract data types. Computer-executable instructions, associated data structures, and program modules represent examples of the program code means for executing operations of the methods disclosed herein. The particular sequence of such executable instructions or associated data structures represents examples of corresponding acts for implementing the functions described in such operations.

Other embodiments of the disclosure may be practiced in network computing environments with many types of computer system configurations, including personal computers, hand-held devices, multi-processor systems, microprocessor-based or programmable consumer electronics, network Personal Computers (PCs), minicomputers, mainframe computers, and the like. Embodiments may also be practiced in distributed computing environments where tasks are performed by local and remote processing devices that are linked (either by hardwired links, wireless links, or by a combination thereof) through a communications network. In a distributed computing environment, program modules may be located in both local and remote memory storage devices.

The various embodiments described above are provided by way of illustration only and should not be construed to limit the scope of the disclosure. For example, the principles herein apply equally to optimization as well as general improvements. Various modifications and changes may be made to the principles described herein without following the example embodiments and applications illustrated and described herein, and without departing from the spirit and scope of the disclosure. Claim language reciting “at least one of” a set indicates that one member of the set or multiple members of the set satisfy the claim.

Claim language or other language in the disclosure reciting “at least one of” a set and/or “one or more” of a set indicates that one member of the set or multiple members of the set (in any combination) satisfy the claim. For example, claim language reciting “at least one of A and B” or “at least one of A or B” means A, B, or A and B. In another example, claim language reciting “at least one of A, B, and C” or “at least one of A, B, or C” means A, B, C, or A and B, or A and C, or B and C, or A and B and C. The language “at least one of” a set and/or “one or more” of a set does not limit the set to the items listed in the set. For example, claim language reciting “at least one of A and B” or “at least one of A or B” can mean A, B, or A and B, and can additionally include items not listed in the set of A and B.

Illustrative examples of the disclosure include:
Aspect 1. A computer-implemented method comprising: accessing road data generated in association with operation of an autonomous vehicle (AV) in a real-world environment; generating a simulation environment for running a software stack associated with controlling the AV based on the road data; modifying a portion of the software stack to generate a modified software stack as part of a test of the modified software stack; running the modified software stack as part of the test using sensor data included as part of the road data as input in running the modified software stack in the simulation environment; and validating the test of the modified software stack based on the running of the modified software stack in the simulation environment in relation to the operation of the AV in the real-world environment.
Aspect 2. The computer-implemented method of Aspect 1, wherein the test of the modified software stack is validated based on a position of the AV in the test in relation to a position of the AV in the real-world environment.
Aspect 3. The computer-implemented method of any of Aspects 1 and 2, wherein the test of the modified software stack is validated based on an orientation of the AV in the test in relation to an orientation of the AV in the real-world environment.
Aspect 4. The computer-implemented method of any of Aspects 1 through 3, wherein validating the test of the modified software stack further comprises: identifying a simulated path of the AV created by running the test of the modified software stack in the simulation environment; identifying a real-world path of the AV in the operation of the AV in the real-world environment; determining a quantification of an amount of divergence between the simulated path of the AV and the real-world path of the AV; and validating the test of the modified software stack based on the quantification of the amount of divergence between the simulated path of the AV and the real-world path of the AV.
Aspect 5. The computer-implemented method of any of Aspects 1 through 4, wherein validating the test of the modified software stack further comprises: identifying an intent of the test of the modified software stack in relation to the operation of the AV in the real-world environment; identifying actual characteristics of the test of the modified software stack in relation to the operation of the AV in the real-world environment; and validating the test of the modified software stack based on a comparison of the intent of the test of the modified software stack and the actual characteristics of the test of the modified software stack in relation of the operation of the AV in the real-world environment.
Aspect 6. The computer-implemented method of any of Aspects 1 through 5, wherein validating the test of the modified software stack further comprises: identifying a real-world intent of the AV in the operation of the AV in the real-world environment; identifying a simulated intent of the AV in the test of the modified software stack in the simulation environment; and validating the test of the modified software stack based on a comparison of the real-world intent of the AV and the simulated intent of the AV.
Aspect 7. The computer-implemented method of any of Aspects 1 through 6, wherein validating the test of the modified software stack further comprises: identifying a real-world perception output of the AV in the operation of the AV in the real-world environment; identifying a simulated perception output of the AV in the test of the modified software stack in the simulation environment; and validating the test of the modified software stack based on a comparison of the real-world perception output and the simulated perception output.
Aspect 8. The computer-implemented method of any of Aspects 1 through 7, wherein the real-world perception output and the simulated perception output are compared based on ray tracing.
Aspect 9. The computer-implemented method of any of Aspects 1 through 8, further comprising facilitating implementation of the modified software stack in real-world operation of the AV based on whether the test of the modified software stack is validated.
Aspect 10. A system comprising: one or more processors; and at least one computer-readable storage medium having stored therein instructions which, when executed by the one or more processors, cause the one or more processors to: access road data generated in association with operation of an autonomous vehicle (AV) in a real-world environment; generate a simulation environment for running a software stack associated with controlling the AV based on the road data; modify a portion of the software stack to generate a modified software stack as part of a test of the modified software stack; run the modified software stack as part of the test using sensor data included as part of the road data as input in running the modified software stack in the simulation environment; and validate the test of the modified software stack based on the running of the modified software stack in the simulation environment in relation to the operation of the AV in the real-world environment.
Aspect 11. The system of Aspect 10, wherein the test of the modified software stack is validated based on a position of the AV in the test in relation to a position of the AV in the real-world environment.
Aspect 12. The system of any of Aspects 10 and 11, wherein the test of the modified software stack is validated based on an orientation of the AV in the test in relation to an orientation of the AV in the real-world environment.
Aspect 13. The system of any of Aspects 10 through 12, wherein validating the test of the modified software stack further comprises: identifying a simulated path of the AV created by running the test of the modified software stack in the simulation environment; identifying a real-world path of the AV in the operation of the AV in the real-world environment; determining a quantification of an amount of divergence between the simulated path of the AV and the real-world path of the AV; and validating the test of the modified software stack based on the quantification of the amount of divergence between the simulated path of the AV and the real-world path of the AV.
Aspect 14. The system of any of Aspects 10 through 13, wherein validating the test of the modified software stack further comprises: identifying an intent of the test of the modified software stack in relation to the operation of the AV in the real-world environment; identifying actual characteristics of the test of the modified software stack in relation to the operation of the AV in the real-world environment; and validating the test of the modified software stack based on a comparison of the intent of the test of the modified software stack and the actual characteristics of the test of the modified software stack in relation of the operation of the AV in the real-world environment.
Aspect 15. The system of any of Aspects 10 through 14, wherein validating the test of the modified software stack further comprises: identifying a real-world intent of the AV in the operation of the AV in the real-world environment; identifying a simulated intent of the AV in the test of the modified software stack in the simulation environment; and validating the test of the modified software stack based on a comparison of the real-world intent of the AV and the simulated intent of the AV.
Aspect 16. The system of any of Aspects 10 through 15, wherein validating the test of the modified software stack further comprises: identifying a real-world perception output of the AV in the operation of the AV in the real-world environment; identifying a simulated perception output of the AV in the test of the modified software stack in the simulation environment; and validating the test of the modified software stack based on a comparison of the real-world perception output and the simulated perception output.
Aspect 17. The system of any of Aspects 10 through 16, wherein the real-world perception output and the simulated perception output are compared based on ray tracing.
Aspect 18. The system of any of Aspects 10 through 17, further comprising facilitating implementation of the modified software stack in real-world operation of the AV based on whether the test of the modified software stack is validated.
Aspect 19. A non-transitory computer-readable storage medium having stored therein instructions which, when executed by one or more processors, cause the one or more processors to: access road data generated in association with operation of an autonomous vehicle (AV) in a real-world environment; generate a simulation environment for running a software stack associated with controlling the AV based on the road data; modify a portion of the software stack to generate a modified software stack as part of a test of the modified software stack; run the modified software stack as part of the test using sensor data included as part of the road data as input in running the modified software stack in the simulation environment; and validate the test of the modified software stack based on the running of the modified software stack in the simulation environment in relation to the operation of the AV in the real-world environment.
Aspect 20. The non-transitory computer-readable storage medium of Aspect 19, wherein the test of the modified software stack is validated based on either or both a position and an orientation of the AV in the test in relation to either or both a position and an orientation of the AV in the real-world environment.
Aspect 21. A system comprising means for performing a method according to any of Aspects 1 through 9.

What is claimed is:

1. A computer-implemented method comprising:
accessing road data generated in association with operation of an autonomous vehicle (AV) in a real-world environment;
generating a simulation environment for running a software stack associated with controlling the AV based on the road data;
modifying a portion of the software stack to generate a modified software stack as part of a test of the modified software stack;
running the modified software stack as part of the test using sensor data included as part of the road data as input in running the modified software stack in the simulation environment; and
validating the test of the modified software stack based on the running of the modified software stack in the simulation environment in relation to the operation of the AV in the real-world environment.

2. The computer-implemented method of claim 1, wherein the test of the modified software stack is validated based on a position of the AV in the test in relation to a position of the AV in the real-world environment.

3. The computer-implemented method of claim 1, wherein the test of the modified software stack is validated based on an orientation of the AV in the test in relation to an orientation of the AV in the real-world environment.

4. The computer-implemented method of claim 1, wherein validating the test of the modified software stack further comprises:
identifying a simulated path of the AV created by running the test of the modified software stack in the simulation environment;
identifying a real-world path of the AV in the operation of the AV in the real-world environment;
determining a quantification of an amount of divergence between the simulated path of the AV and the real-world path of the AV; and
validating the test of the modified software stack based on the quantification of the amount of divergence between the simulated path of the AV and the real-world path of the AV.

5. The computer-implemented method of claim 1, wherein validating the test of the modified software stack further comprises:
identifying an intent of the test of the modified software stack in relation to the operation of the AV in the real-world environment;
identifying actual characteristics of the test of the modified software stack in relation to the operation of the AV in the real-world environment; and
validating the test of the modified software stack based on a comparison of the intent of the test of the modified software stack and the actual characteristics of the test of the modified software stack in relation of the operation of the AV in the real-world environment.

6. The computer-implemented method of claim 1, wherein validating the test of the modified software stack further comprises:
identifying a real-world intent of the AV in the operation of the AV in the real-world environment;
identifying a simulated intent of the AV in the test of the modified software stack in the simulation environment; and
validating the test of the modified software stack based on a comparison of the real-world intent of the AV and the simulated intent of the AV.

7. The computer-implemented method of claim 1, wherein validating the test of the modified software stack further comprising:
identifying a real-world perception output of the AV in the operation of the AV in the real-world environment;
identifying a simulated perception output of the AV in the test of the modified software stack in the simulation environment; and
validating the test of the modified software stack based on a comparison of the real-world perception output and the simulated perception output.

8. The computer-implemented method of claim 7, wherein the real-world perception output and the simulated perception output are compared based on ray tracing.

9. The computer-implemented method of claim 1, further comprising facilitating implementation of the modified software stack in real-world operation of the AV based on whether the test of the modified software stack is validated.

10. A system comprising:
one or more processors; and
at least one computer-readable storage medium having stored therein instructions which, when executed by the one or more processors, cause the one or more processors to:
access road data generated in association with operation of an autonomous vehicle (AV) in a real-world environment;
generate a simulation environment for running a software stack associated with controlling the AV based on the road data;
modify a portion of the software stack to generate a modified software stack as part of a test of the modified software stack;
run the modified software stack as part of the test using sensor data included as part of the road data as input in running the modified software stack in the simulation environment; and
validate the test of the modified software stack based on the running of the modified software stack in the simulation environment in relation to the operation of the AV in the real-world environment.

11. The system of claim 10, wherein the test of the modified software stack is validated based on a position of the AV in the test in relation to a position of the AV in the real-world environment.

12. The system of claim 10, wherein the test of the modified software stack is validated based on an orientation of the AV in the test in relation to an orientation of the AV in the real-world environment.

13. The system of claim 10, wherein the instructions further cause the one or more processors to:
identify a simulated path of the AV created by running the test of the modified software stack in the simulation environment;
identify a real-world path of the AV in the operation of the AV in the real-world environment;
determine a quantification of an amount of divergence between the simulated path of the AV and the real-world path of the AV; and
validate the test of the modified software stack based on the quantification of the amount of divergence between the simulated path of the AV and the real-world path of the AV.

14. The system of claim 10, wherein the instructions further cause the one or more processors to:
identify an intent of the test of the modified software stack in relation to the operation of the AV in the real-world environment;
identify actual characteristics of the test of the modified software stack in relation to the operation of the AV in the real-world environment; and
validate the test of the modified software stack based on a comparison of the intent of the test of the modified software stack and the actual characteristics of the test of the modified software stack in relation of the operation of the AV in the real-world environment.

15. The system of claim 10, wherein the instructions further cause the one or more processors to:
identify a real-world intent of the AV in the operation of the AV in the real-world environment;
identify a simulated intent of the AV in the test of the modified software stack in the simulation environment; and
validate the test of the modified software stack based on a comparison of the real-world intent of the AV and the simulated intent of the AV.

16. The system of claim 10, wherein the instructions further cause the one or more processors to:
identify a real-world perception output of the AV in the operation of the AV in the real-world environment;
identify a simulated perception output of the AV in the test of the modified software stack in the simulation environment; and
validate the test of the modified software stack based on a comparison of the real-world perception output and the simulated perception output.

17. The system of claim 16, wherein the real-world perception output and the simulated perception output are compared based on ray tracing.

18. The system of claim 10, wherein the instructions further cause the one or more processors to facilitate implementation of the modified software stack in real-world operation of the AV based on whether the test of the modified software stack is validated.

19. A non-transitory computer-readable storage medium having stored therein instructions which, when executed by one or more processors, cause the one or more processors to:
access road data generated in association with operation of an autonomous vehicle (AV) in a real-world environment;
generate a simulation environment for running a software stack associated with controlling the AV based on the road data;
modify a portion of the software stack to generate a modified software stack as part of a test of the modified software stack;
run the modified software stack as part of the test using sensor data included as part of the road data as input in running the modified software stack in the simulation environment; and
validate the test of the modified software stack based on the running of the modified software stack in the simulation environment in relation to the operation of the AV in the real-world environment.

20. The non-transitory computer-readable storage medium of claim 19, wherein the test of the modified software stack is validated based on either or both a position and an orientation of the AV in the test in relation to either or both a position and an orientation of the AV in the real-world environment.
